(19) United States
(12) Patent Application Publication
(10) Pub. No.: US 2012/0282401 A1
(43) Pub. Date: Nov. 8, 2012

(54) METHOD OF FORMING A PARTIAL DEPOSITION LAYER AND APPARATUS OF FORMING A PARTIAL DEPOSITION LAYER

(75) Inventors: Chun-Yuan Lee, New Taipei City (TW); Wei-Hsiang Huang, Taoyuan County (TW); Shu-Yin Cheng, Taoyuan County (TW)

(73) Assignee: Etansi Inc., Taoyuan County (TW)

(21) Appl. No.: 13/101,161

(22) Filed: May 5, 2011

(51) Int. Cl. C23C 16/04; C23C 16/448; C23C 16/458; C23C 16/06

(52) U.S. Cl. 427/251; 427/255.5; 118/720

(57) ABSTRACT

A method of forming a partial deposition layer and an apparatus of forming the partial deposition layer are provided. A substrate is provided over an evaporation plate. A shielding plate is placed between the evaporation plate and the substrate such that the shielding plate shields a first portion of the substrate and exposes a second portion of the substrate. An evaporation process is performed when the substrate is moving in a predetermined direction such that a evaporation source on the evaporation plate is deposited on the exposed second portion of the substrate but not deposited on the shielded first portion of the substrate.

### FIELD OF THE PRESENT INVENTION

The present invention generally relates to a method of forming a partial deposition layer and an apparatus of forming a partial deposition layer, in particular, to a method of forming a partial deposition layer without using a washing process to removed the non-necessary portions of the deposition layer and an apparatus of the same.

### DESCRIPTION OF RELATED ART

A decoration film is consisted of a substrate and a plurality material layers formed thereon, wherein the substrate can be a flexible substrate such that the decoration film can be applied in an in-mold decoration (IMD) process, an in-mold rolling (IMR) process, and the like. The decoration film is used for providing certain visual effect in a device or a housing of a device, such as providing a metallic luster, presenting certain pattern (i.e. trade mark, logo, etc.), or present certain color. Even certain touch sensing effect can be achieved by the decoration film.

Generally, for providing the metallic luster or providing the pattern with metallic luster, the material layers formed on the substrate of the decoration film at least includes one metal layer, wherein a material of the metal layer is preferred Ag for achieving high brightness. However, a decoration film having an Ag layer formed on the overall surface of the substrate has electrically shielding effect so that an electronic device using such decoration film may have poor wireless-signal transmission quality. Accordingly, for having desirable appearance without negatively influence on the quality of the electronic device, the Ag layer formed on the substrate is usually patterned so that the Ag layer is partially retained on the substrate without shielding the transmission of the wireless-signal.

Recently, the method of forming the patterned layer of Ag on the substrate includes forming a shielding pattern on the substrate, depositing Ag material on the overall surface of the substrate having the shielding pattern, and washing (or cleaning) the shielding pattern and a portion of the Ag layer deposited thereon. It is noted that such process complicates the fabrication of the decoration film and the agent used for washing the shielding pattern and the portion of the Ag layer may become a pollution to the environment. In addition, if the shielding pattern and the portion of the Ag layer deposited thereon are not completely washed out, a contamination in the decoration film can be caused and the alignment marks original formed on the substrate can be shielded, which negatively influence on the subsequent process such as the fabrication of the decoration film, the subsequent IMD, or the subsequent IMR process. Accordingly, the method of forming a partial metal layer on the substrate is required to be improved.

### SUMMARY OF THE PRESENT INVENTION

Accordingly, the present invention is directed to a method of forming a partial deposition layer having at least the characteristics of simple and low pollution to the environment and the fabricated product.

The present invention is directed to an apparatus of forming a partial deposition layer without using a washing agent.

According to an embodiment of the present invention, a method of forming a partial deposition layer is provided. A substrate is provided over an evaporation plate. A shielding plate is placed between the evaporation plate and the substrate such that the shielding plate shields a first portion of the substrate and exposes a second portion of the substrate. An evaporation process is performed when the substrate is moving in a predetermined direction such that an evaporation source on the evaporation plate is deposited on the exposed second portion of the substrate but not deposited on the shielded first portion of the substrate.

According to an embodiment of the present invention, the evaporation source on the evaporation plate includes metal.

According to an embodiment of the present invention, the evaporation source on the evaporation plate includes Al, Ni, Au, Pt, Cr, Fe, Cu, Sn, Ag. Ti, Pb, Zn, or a combination thereof.

According to an embodiment of the present invention, a portion of the evaporation source on the evaporation plate is deposited on a side of the shielding plate away from the substrate.

According to an embodiment of the present invention, a patterned ink layer is further formed on the substrate before the substrate is provided over the evaporation plate, wherein the patterned ink layer has at least one patterned opening such that the evaporation source on the evaporation plate is at least deposited in the patterned opening.

According to an embodiment of the present invention, the substrate has an alignment mark formed thereon before the substrate is provided over the evaporation plate and the alignment is located in the shielded first portion of the substrate

According to an embodiment of the present invention, the substrate includes a flexible substrate or a glass substrate.

According to an embodiment of the present invention, a location of the shielding plate is adjustable.

According to an embodiment of the present invention, the evaporation source on the evaporation plate is heated through a heater such that the evaporation source is evaporated and deposited on the exposed second portion of the substrate.

According to an embodiment of the present invention, an apparatus of forming a partial deposition layer is provided. The apparatus of forming the partial deposition layer includes a chamber, a carrier, and a shielding plate. The chamber has an evaporation plate disposed therein. The carrier is disposed in the chamber and located over the evaporation plate for carrying a substrate and moving the substrate in a predetermined direction. The shielding plate is disposed between the evaporation plate and the carrier, wherein the shielding plate shields a first portion of the substrate and exposes a second portion of the substrate.

According to an embodiment of the present invention, an evaporation source on the evaporation plate includes metal.

According to an embodiment of the present invention, an evaporation source on the evaporation plate includes Al, Ni, Au, Pt, Cr, Fe, Cu, Sn, Ag, Ti, Pb, Zn, or a combination thereof.

According to an embodiment of the present invention, the carrier includes a roller for rotating in the predetermined direction and the substrate is placed on the roller.

According to an embodiment of the present invention, the substrate includes a flexible substrate or a glass substrate.

According to an embodiment of the present invention, the apparatus of forming the partial deposition layer further includes a supporter placed in the chamber for supporting the shielding substrate.

According to an embodiment of the present invention, a number of the shielding plate is one or more.

According to an embodiment of the present invention, the apparatus of forming the partial deposition layer further includes a heater for heating the evaporation plate.

According to an embodiment of the present invention, a distance from the substrate to the shielding plate is from 0.1 cm to 5 cm.

According to an embodiment of the present invention, a distance from the substrate to the shielding plate is from 0.5 cm to 1 cm.

In view of the above, the apparatus of forming a partial deposition layer includes a shielding plate placed in the chamber and located between the substrate to be deposited the partial deposition layer thereon and the evaporation plate, such that the evaporation path of the evaporation source on the evaporation plate is shielded by the shielding plate and merely a second portion of the substrate is deposited with the evaporation source. The method of forming the partial deposition layer according to an embodiment of the present invention does not require any washing process or cleaning process and the partial deposition layer is formed right after the evaporation process is performed. Accordingly, the problem of pollution is prevented and the method is easy.

In order to make the aforementioned and other features and advantages of the present invention more comprehensible, embodiments accompanying figures are described in detail below.

Herein, the same or similar reference numbers used in the drawings and the descriptions are referred as the same or similar elements. For clearly describing the concept of the present invention, the shapes and the thickness of the elements in the embodiments accompanying with the drawings may not definitely comply with the real circumstance. In addition, the following descriptions are directed to the elements or the combinations thereof, but the elements are not particularly restricted in the contents or the descriptions. Any form or shape known by one skilled in the art is applicable in the present invention. Moreover, the description that a material layer disposed on a substrate or disposed on another material layer means that the material layer is directly located on the substrate or the another material layer, and may also mean that some interlayer is interrupted between the material layer and the substrate or between the material layer and the another material layer.

### BRIEF DESCRIPTION OF THE DRAWINGS

The accompanying drawings are included to provide a further understanding of the present invention, and are incorporated in and constitute a part of this specification. The drawings illustrate embodiments of the present invention and, together with the description, serve to explain the principles of the present invention.

FIG. 1 schematically illustrates an apparatus of forming a partial deposition layer according to an embodiment of the present invention.

FIG. 2 schematically illustrates a top view of a portion components of the apparatus depicted in FIG. 1, wherein the substrate 150 carried by the roller 122, the shielding plate 140, and the supporter 142 are shown.

FIG. 3 schematically illustrates a side view of a portion components of the apparatus depicted in FIG. 1, wherein the substrate 150 carried by the roller 122, the shielding plate 140, and the supporter 142 are shown.

FIG. 4 schematically illustrates a cross-sectional view taken along line A-A′ of FIG. 2 when the deposition process is performed according to an embodiment of the present invention.

FIG. 5 schematically illustrates a partial layer formed on a substrate by using the apparatus depicted in FIG. 1 according to an embodiment of the present invention.

FIG. 6 schematically illustrate a top view of a partial layer formed on a substrate by using the apparatus depicted in FIG. 1 according to another embodiment of the present invention.

FIG. 7 schematically illustrate a cross-sectional view taken along line B-B′ FIG. 6.

### DESCRIPTION OF THE EMBODIMENTS

Reference will now be made in detail to the present embodiments of the present invention, examples of which are illustrated in the accompanying drawings. Wherever possible, the same reference numbers are used in the drawings and the description to refer to the same or like parts.

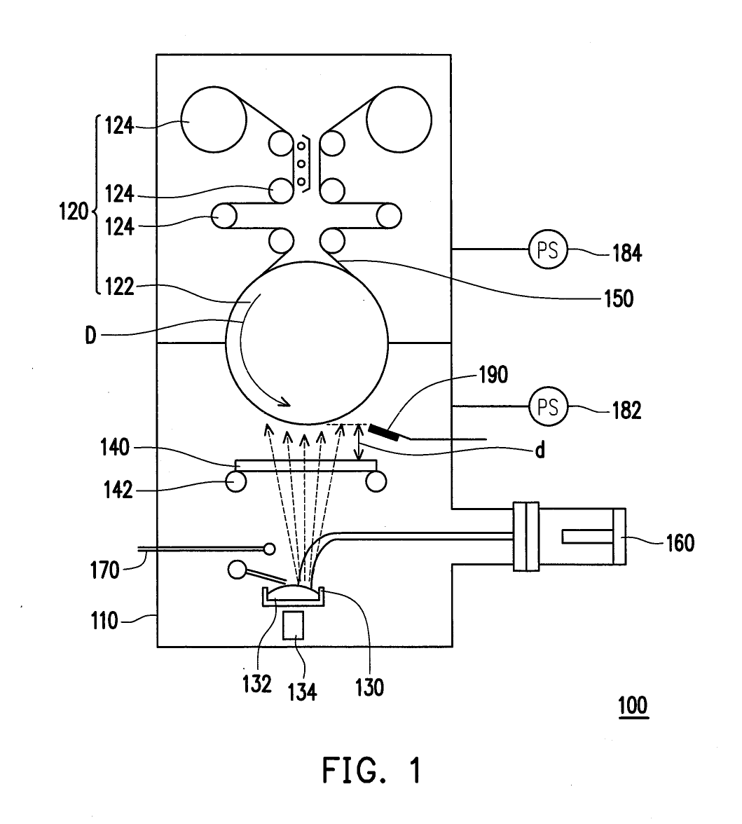

FIG. 1 schematically illustrates an apparatus of forming a partial deposition layer according to an embodiment of the present invention. Referring to FIG. 1, the apparatus 100 includes a chamber 110, a carrier 120, an evaporation plate 130, and a shielding plate 140, wherein the carrier 120, the evaporation plate 130, and the shielding plate 140 are configured inside the chamber 110. The carrier 120 is used for carrying a substrate 150 and located opposite to the evaporation plate 130, wherein an evaporation source 132 is placed in the evaporation plate 130. The shielding plate 140 is located between the evaporation plate 130 and the substrate 150 carried by the carrier 120. Herein, the substrate 150 can be a flexible substrate and the carrier 120 can be constituted by a plurality of roller 122 and 124, wherein the roller 122 is configured right opposite to the evaporation plate 130 such that the deposition process can be performed on the substrate 150 carried by the roller 122. Nevertheless, the present invention is not restricted thereto. In other embodiments, the substrate 150 can be a glass substrate and the carrier 120 can be a carrier plate or the like.

The apparatus 100 can further includes a heater 134, a feeder 160, a vacuum detecting meter 170, and pumping systems 182 and 184. The feeder 160 is used for providing the evaporation source 132 to the evaporation plate 130, such that the evaporation source 132 on the evaporation plate 130 is heated by the heater 134, which facilitates the evaporation source 132 being evaporated and subsequently deposited on the substrate 150. In addition, the pumping systems 182 and 184 are used for maintaining the pressure inside the chamber 110. An optical density monitor 190 can be further placed in the chamber 110 for observing the formation of the deposition layer and detecting the formed thickness of the deposition layer on the substrate 150. It is noted that the heater 134, the feeder 160, the vacuum detecting meter 170, and the pumping systems 182 and 184 are exemplarily shown in FIG. 1, but the present invention is not intent to be limited herein. In other embodiment, any known designs of those components can be applied in the apparatus 100.

Specifically, for supporting the shielding plate 140 located between the substrate 150 and the evaporation plate 130, a supporter 142 can be placed in the chamber 110. Herein, the location of the shielding plate 140 can be adjusted according to the requirement so that the supporter 142 may include a position adjusting mechanism (nor shown). When the distance d between the substrate 150 and the shielding plate 140 is required to be reduced or increase, the position adjusting mechanism (not shown) can facilitate the shielding plate 140 to move close to the substrate 150 or away from the substrate 150 vertically. It is noted that in a common situation, the distance d can be from 0.1 cm to 5 cm, or from 0.5 cm to 1 cm. Furthermore, the horizontal position of the shielding plate 140 can also be adjusted according to the requirement.

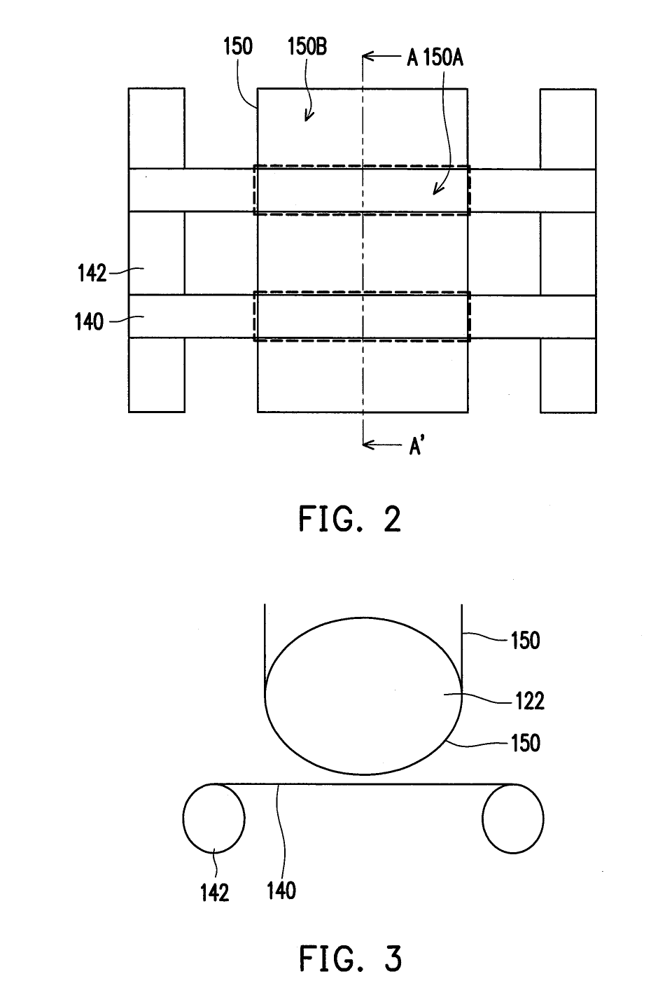

FIGS. 2 and 3 schematically illustrate a top view and a side view of a portion components of the apparatus depicted in FIG. 1, wherein the substrate 150 carried by the roller 122, the shielding plate 140, and the supporter 142 are shown. Referring to FIG. 1, FIG. 2, and FIG. 3 together, in the present embodiment, a number of the shielding plate 140 is two, but the present invention is not limited to such configuration. In other embodiments, the number of the shielding plate 140 can be one or more than two according to the requirement of the user. The shielding plates 140 shield a first portion 150A of the substrate 150 and expose the second portion 150B of the substrate 150. Accordingly, when the apparatus 100 illustrated in FIG. 1 is worked and a deposition process is performed, the evaporation source 132 on the evaporation plate 130 can be deposited on the exposed second portion 150B of the substrate 150. In the present embodiment, the location of the two shielding plates 140 can be adjusted based on the specific requirement so that the first portion 150A and the second portion 150B can be arranged in another manner, which is not particularly limited in the present embodiment.

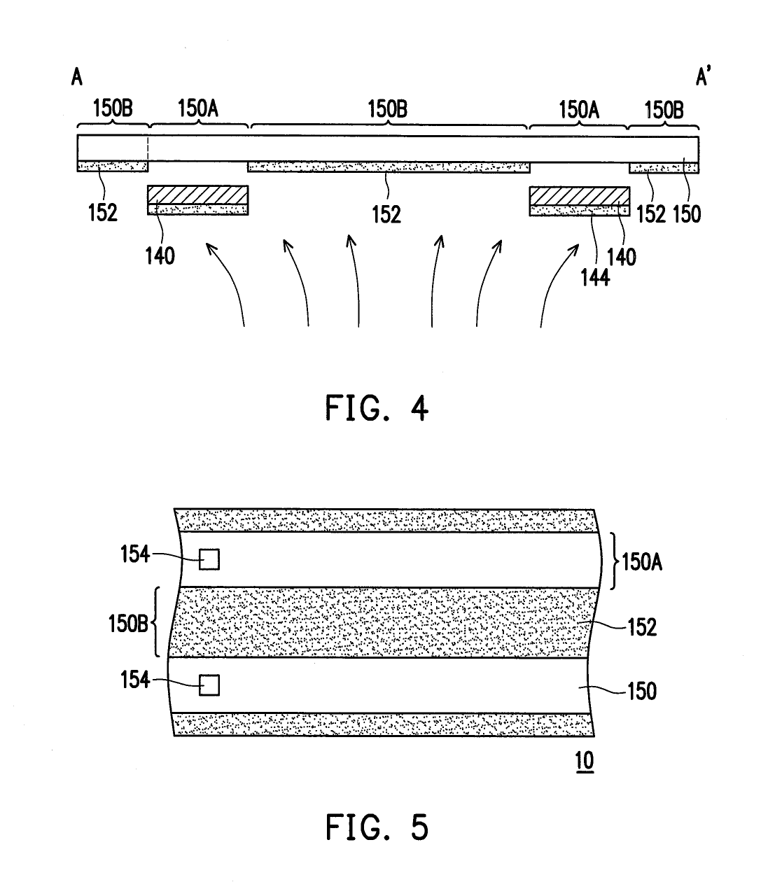

In detail, FIG. 4 schematically illustrates a cross-sectional view taken along line A-A′ of FIG. 2 when the deposition process is performed according to an embodiment of the present invention. Referring to FIG. 1 and FIG. 4 simultaneously, the shielding plate 140 is located between the substrate 150 and the evaporation plate 130, such that a partial deposition layer 152 can be formed on the substrate 150 when the deposition process is performed. Namely, the shielding effect of the shielding plate 140 renders the second portion 150B of the substrate 150 is deposited by the material of the evaporation plate 130 but the first portion 150A of the substrate 150 is not deposited by the material of the evaporation plate 130. Particularly, certain portion of the evaporation source 132 on the evaporation plate 130 is deposited on the shielding plate 140 so that a material layer 144 can be formed on a side of the shielding plate 140 away from the substrate 150 during the deposition process.

In a word, the method of forming the partial deposition layer 152 on the substrate 150 according to the present embodiment includes providing the substrate 150 over the evaporation plate 130, placing the shielding plate 140 between the evaporation plate 130 and the substrate 150 such that the shielding plate 140 shields the first portion 150A of the substrate 150 and exposes second portion 150B of the substrate 150, and performing the evaporation process. In the present embodiment, the roller 122 of the carrier 120 can rotates in a predetermined direction D during the deposition process, such that the substrate 150 can be moved in the predetermined direction D during being subjected to the deposition process. When the substrate 150 is moving in the predetermined direction D, the evaporation source 132 on the evaporation plate 130 is continuously deposited on the exposed second portion 150B of the substrate 150 but not deposited on the shielded first portion 150A of the substrate 150 so as to form the partial deposition layer 152 on the substrate 150.

According to the present embodiment, the evaporation source 132 on the evaporation plate 130 is metal which can include Al, Ni, Au, Pt, Cr, Fe, Cu, Sn, Ag. Ti, Pb, Zn, or a combination thereof so that the partial deposition layer 152 formed on the substrate 150 is consisted of metal or the material mentioned above. The partial deposition layer 152 consisted of metal material can provide the visual effect of metallic luster. When the substrate 150 with the partial deposition layer 152 formed thereon is served as a decoration film, the decorated device or decorated housing of a device can have desirable visual effect of metallic luster.

It has been known that the metal layer formed on the overall surface of the substrate 150 may have the electric shielding effect which is unsuitable for being served as the decoration film in the electronic device. Nevertheless, the partial deposition layer 152 in the present embodiment merely formed on the second portion 150B of the substrate 150 can prevent from such problem. For example, the first portion 150A of the substrate 150 without deposited by the partial deposition layer 152 can be corresponding to the wireless transmission element of the decorated device such as an antenna. As such, the quality of the wireless signal transmission in the decorated device is not negatively influenced by the configuration of the partial deposition layer 152 made of metal or other conductive material. Furthermore, the manufacturer or the user can modify the thickness, of the partial deposition layer 152 by controlling the deposition process to obtain the required visual effect of metallic luster without considering the problem of the electric shielding effect. That is to say, the thickness of the partial deposition layer 152 is not restricted in the present embodiment.

In addition, under the configuration of the shielding plates 140, the formation of the partial deposition layer 152 does not require any process for removing a portion of the evaporation source 132 on the evaporation plate 130 from the substrate 150. Accordingly, no shielding pattern is required to be formed on the substrate 150 and subsequently be washed out, which is conducive to simplify the fabrication process and prevent from the pollution problem caused by the agent used in the washing process. The method of forming the partial deposition layer 152 according to the present embodiment is simple, environmental friendly, and cheap.

FIG. 5 schematically illustrates a partial layer formed on a substrate by using the apparatus depicted in FIG. 1 according to an embodiment of the present invention. Referring to FIG. 5, the substrate 150 is formed with the partial deposition layer 152 and the substrate 150 can originally have the alignment marks 154 such that the substrate 150 with the elements formed thereon constitutes a decoration film 10 capable of applying in the IMD process or the IMR process for decorating a device or a housing of a device. It is noted that the location of the shielding plates 140 as shown in FIG. 1 shield the position where the alignment marks 154 are, which maintains the alignment function of the alignment marks 154 by not being shielded.

In the present embodiment, the partial deposition layer 152 is not formed on the first portion 150A of the substrate 150 and the alignment marks 154 are located in the first portion 150A of the substrate 150. Accordingly, the alignment marked 154 are not cover or shielded by the partial deposition layer 152 and can provide the alignment effect, which facilitates the decoration film 10 being applied in the subsequent process such the formation of other material layers, the IMD process, or the IMD process because the subsequent process requires good alignment accuracy. It is noted that the alignment marks 154 depicted herein is exemplarily shown, but not intent to limit the scope of the present invention. In an alternative embodiment, the alignment marks 154 can have other shapes or can optionally be omitted from the substrate 150.

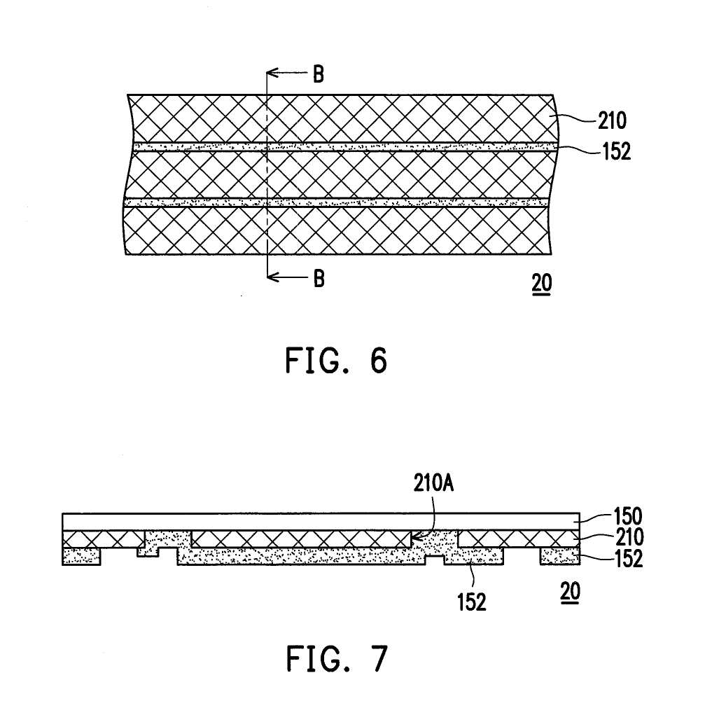

FIG. 6 schematically illustrate a top view of a partial layer formed on a substrate by using the apparatus depicted in FIG. 1 according to another embodiment of the present invention and FIG. 7 schematically illustrate a cross-sectional view taken along line B-B′ FIG. 6. Referring to FIG. 1, FIGS. 6, and 7, the substrate 150 are formed with the patterned ink layer 210 and the partial deposition layer 152 to constitute the decoration film 20 according the present embodiment. It is noted that the patterned ink layer 210 is covered by the partial deposition layer 152 so that the pattern ink layer 210 can be formed before the substrate 150 is provided over the evaporation plate 130 depicted in FIG. 1 for forming the partial deposition layer 152. That is to say, the substrate 150 can have certain material layer originally formed thereon before being subjected to the deposition process in the apparatus 100 depicted in FIG. 1.

In the present embodiment, the patterned ink layer 210 has at least one patterned opening 210A such that the evaporation source 132 on the evaporation plate 130 is at least deposited in the patterned opening 210A. That is to say, the partial deposition layer 152 is at least located in the patterned openings 210A so that the decoration film 20 can have the required visual effect. Specifically, the decoration film 20 can present specific color by the patterned ink layer 210 and present specific pattern with metallic luster by the partial deposition layer 152 located in the patterned openings 210A. It is noted that the patterned openings 210A illustrated in FIG. 6 are stripe openings but the present invention is not limited thereto. In an alternative embodiment, the shapes of the patterned openings 210A can be modified according to the requirement.

In summary, the partial deposition layer is formed on the substrate by a deposition process without additional washing process or additional cleaning process in an embodiment of the present invention. Accordingly, the method of forming the partial layer according the present invention is simple and easy. In addition, the agent used for the washing process or the cleaning process is not required in the method of forming the partial deposition layer according to the present invention, which presents the pollution problem caused by the used agent. Therefore, the method of forming the partial layer according to the present invention is environment friendly. In addition, the apparatus of forming the partial deposition layer is simple by placing a shielding plate in the deposition chamber between the substrate and the evaporation plate in the present invention.

It will be apparent to those skilled in the art that various modifications and variations can be made to the structure of the present invention without departing from the scope or spirit of the present invention. In view of the foregoing, it is intended that the present invention cover modifications and variations of this invention provided they fall within the scope of the following claims and their equivalents.

What is claimed is:

1. A method of forming a partial deposition layer comprising:
providing a substrate over an evaporation plate;
placing a shielding plate between the evaporation plate and the substrate such that the shielding plate shields a first portion of the substrate and exposes a second portion of the substrate; and
performing an evaporation process when the substrate is moving in a predetermined direction such that an evaporation source on the evaporation plate is deposited on the exposed second portion of the substrate and outside of the shielded first portion of the substrate.

2. The method of forming a partial deposition layer according to claim 1, wherein the evaporation source on the evaporation plate comprises metal.

3. The method of forming a partial deposition layer according to claim 1, wherein the evaporation source on the evaporation plate comprises Al, Ni, Au, Pt, Cr, Fe, Cu, Sn, Ag. Ti, Pb, Zn, or a combination thereof.

4. The method of forming a partial deposition layer according to claim 1, wherein a portion of the evaporation source on the evaporation plate is deposited on a side of the shielding plate away from the substrate.

5. The method of forming a partial deposition layer according to claim 1, further comprising forming a patterned ink layer on the substrate before the substrate is provided over the evaporation plate, wherein the patterned ink layer has at least one patterned opening such that the evaporation source on the evaporation plate is at least deposited in the patterned opening.

6. The method of forming a partial deposition layer according to claim 1, wherein the substrate has an alignment mark formed thereon before the substrate is provided over the evaporation plate and the alignment is located in the shielded first portion of the substrate.

7. The method of forming a partial deposition layer according to claim 1, wherein the substrate comprises a flexible substrate or a glass substrate.

8. The method of forming a partial deposition layer according to claim 1, wherein a location of the shielding plate is adjustable.

9. The method of forming a partial deposition layer according to claim 1, wherein the evaporation source on the evaporation plate is heated through a heater such that the evaporation source is evaporated and deposited on the exposed second portion of the substrate.

10. An apparatus of forming a partial deposition layer, comprising:
a chamber having an evaporation plate disposed therein;
a carrier disposed in the chamber and located over the evaporation plate for carrying a substrate and moving the substrate in a predetermined direction; and
a shielding plate disposed between the evaporation plate and the carrier, wherein the shielding plate shields a first portion of the substrate and exposes a second portion of the substrate.

11. The apparatus of forming a partial deposition layer according to claim 10, wherein an evaporation source on the evaporation plate comprises metal.

12. The apparatus of forming a partial deposition layer according to claim 10, wherein an evaporation source on the evaporation plate comprises Al, Ni, Au, Pt, Cr, Fe, Cu, Sn, Ag, Ti, Pb, Zn, or a combination thereof.

13. The apparatus of forming a partial deposition layer according to claim 10, wherein the carrier comprises a roller for rotating in the predetermined direction and the substrate is placed on the roller.

14. The apparatus of forming a partial deposition layer according to claim 10, wherein the substrate comprises a flexible substrate or a glass substrate.

15. The apparatus of forming a partial deposition layer according to claim 10, further comprising a supporter placed in the chamber for supporting the shielding substrate.

16. The apparatus of forming a partial deposition layer according to claim 10, wherein a number of the shielding plate is one or more.

17. The apparatus of forming a partial deposition layer according to claim 10, further comprising a heater for heating the evaporation plate.

18. The apparatus of forming a partial deposition layer according to claim 10, wherein a distance from the substrate to the shielding plate is from 0.1 cm to 5 cm.

19. The apparatus of forming a partial deposition layer according to claim 10, wherein a distance from the substrate to the shielding plate is from 0.5 cm to 1 cm.
